(19) United States
(12) Patent Application Publication
(10) Pub. No.: US 2024/0002722 A1
(43) Pub. Date: Jan. 4, 2024

(54) GREEN FLUORESCENT CERAMIC MATERIAL, PREPARATION METHOD THEREFOR AND USE THEREOF

(71) Applicants: FUJIAN INSTITUTE OF RESEARCH ON THE STRUCTURE OF MATTER, CHINESE ACADEMY OF SCIENCES, Fuzhou, Fujian (CN); FUJIAN CAS-CERAMIC OPTOELECTRONICS TECHNOLOGY CO.,LTD, Fuzhou, Fujian (CN)

(72) Inventors: Youfu ZHOU, Fuzhou, Fujian (CN); Maochun HONG, Fuzhou, Fujian (CN); Junrong LING, Fuzhou, Fujian (CN); Xiuqiang ZHANG, Fuzhou, Fujian (CN)

(21) Appl. No.: 18/252,400

(22) PCT Filed: Nov. 11, 2021
(86) PCT No.: PCT/CN2021/130000

§ 371 Date: May 10, 2023

(30) Foreign Application Priority Data
Nov. 11, 2020 (CN) 202011255704.5

(51) Int. Cl. C09K 11/77; C04B 35/64; C04B 35/44; C04B 35/626

(52) U.S. Cl. CPC C09K 11/7774; C04B 35/64; C04B 35/44; C04B 35/6261; C04B 2235/3222; C04B 2235/9653; C04B 2235/422; C04B 2235/9607; C04B 2235/3225; C04B 2235/3229

(57) ABSTRACT

A green fluorescent ceramic material, a preparation method therefor and the use thereof, are applicable in the field of fluorescent ceramics for LED lighting. The chemical constitution of the green fluorescent ceramic material is graphene-Y_{3-x-y}Al₅O₁₂:x Ce³⁺, y Lu³⁺, with 0.0001≤x≤0.1, and 0.01≤y≤2.9; and the mass percentage of graphene is less than 0.5 wt % but is not 0 on the basis of the total weight of the green fluorescent ceramic material. The green fluorescent ceramic material has the characteristics of a high heat conductivity, a good heat dissipation property, and a controllable light-emitting wavelength within a range of 490-540 nm; and same is suitable for use as an LED encapsulating material.

The present application claims priority to the prior application with the patent application No. 202011255704.5 filed with China National Intellectual Property Administration by the applicant on Nov. 11, 2020 and entitled “GRAPHENE-MODIFIED GREEN-LIGHT TRANSPARENT CERAMIC MATERIAL AND PREPARATION METHOD THEREFOR AND USE THEREOF”. The full text of the prior application is incorporated by reference in the present application.

### TECHNICAL FIELD

The present disclosure relates to the field of transparent fluorescent materials for LEDs, and specifically to a green fluorescent ceramic material, a method for preparing the same and use thereof.

### BACKGROUND

Offering excellent performance including high luminous efficiency, lower power consumption, environmental friendliness, longer lifetime, and the like, LEDs have been widely applied in the fields of outdoor lighting, venue lighting, indoor lighting and the like. In the traditional LED light source, Y₃Al₅O₁₂:Ce (YAG:Ce) fluorescent powder is encapsulated in epoxy resin or silica gel. Due to the poor heat dissipation performance of these organic encapsulating materials, the heat is not easy to dissipate in the operation process of an LED chip, leading to a rise in the temperature of the light source. After an LED light operates for a long time, these organic encapsulating materials will become aged and decomposed, causing problems such as light attenuation, color shift, shortened lifetime, and the like.

The YAG:Ce fluorescent transparent ceramic has higher thermal conductivity and thermal stability, and the use thereof as an LED encapsulating material effectively solves the problems including light attenuation, color shift, shortened lifetime, and the like caused by the poor heat dissipation performance of organic encapsulating materials. When the YAG:Ce fluorescent ceramic is used as a light conversion material, the YAG:Ce fluorescent ceramic-encapsulated LED and the YAG:Ce fluorescent powder-encapsulated LED are both white LEDs, which cannot meet the lighting needs of special occasions. The main applications of green LEDs include: 1) green LEDs can be used in deep-sea fishing; they have higher luminous efficiency and better heat dissipation performance compared with metal halide/traditional encapsulated green LED fish gathering lamps; 2) the combination of green LEDs and red fluorescent materials can achieve full-spectrum lighting, improving the color rendering and luminous quality; and 3) green LEDs have wide application prospect in the fields of underwater visible light communication technology, vegetable cultivation, bird egg hatching, and the like. Nowadays, the market for high-end lighting such as high-power LED special lighting is in the ascendant, and higher requirements are put forward for the luminescence band, heat dissipation performance, and the like of fluorescent ceramics. The luminous quality and thermal conductivity of green fluorescent transparent ceramics for LEDs need to be further improved to meet the encapsulating needs of high-power LEDs.

Lu₃Al₅O₁₂:Ce (LuAG:Ce) is a green fluorescent transparent ceramic with excellent performance, which can not only be effectively excited by blue light but also has excellent thermal stability. It has been reported in the literature (Xu, J., et al., Journal of the European Ceramic Society, 38(1), 343-347) that the luminous intensity of the LuAG:Ce fluorescent ceramic-encapsulated LED only decreased by 4.1% at 220° C., and that the luminous intensity only decreased by 1.9% after 1000 h of continuous operation. A LuAG:Ce green fluorescent ceramic is disclosed in the patent literature CN201510234002.1, but expensive lutetium (Lu) leading to relatively high production costs greatly limits the application of the LuAG:Ce ceramic. Graphene is a two-dimensional material with excellent performance and has high transmittance and high thermal conductivity (3500 Wm⁻¹ K⁻¹). Many studies have shown that the introduction of graphene into ceramic substrates such as TiC, Al₂O₃, AlN, SiO₂, Si₃N₄, SiC, etc. can lead to remarkable effects in terms of mechanical performance, thermal performance, electrical performance and the like. If 2 wt % of graphene is introduced into a SiC substrate, the thermal conductivity can be increased from 114 Wm⁻¹ K⁻¹ to 145 Wm⁻¹ K⁻¹. Since the introduction of graphene will hinder the sintering densification of ceramic substrates, hot pressing sintering, spark plasma sintering, high-frequency induction heating sintering and other sintering methods with strict requirements for equipments are usually adopted to prepare graphene-ceramic composite materials. The vacuum sintering method is easier than the above methods to prepare large, complex ceramic products, and also provides an additional driving force to eliminate air pores and promote the densification of the products. The preparation of YAG:Ce/LuAG:Ce fluorescent ceramics by vacuum sintering method requires annealing in air to eliminate oxygen vacancy defects, while graphene is prone to oxidize and decompose when annealed in air. Therefore, it is a very challenging task to prepare a graphene-modified densified fluorescent ceramic composite material by vacuum sintering method.

### SUMMARY

The present disclosure provides a green fluorescent ceramic material, which has a chemical composition of graphene-Y_{3-x-y}Al₅O₁₂:x Ce³⁺, y Lu³⁺, with 0.0001≤x≤0.1, and 0.01≤y≤2.9; and based on the total weight of the green fluorescent ceramic material, a mass percentage of the graphene is less than 0.5 wt % but is not 0.

According to an embodiment of the present disclosure, x is in a range of 0.0005≤x≤0.06, preferably 0.001≤x≤0.01, and is exemplarily 0.0001, 0.0005, 0.001, 0.0015, 0.003, 0.005, 0.007, 0.01, 0.02, 0.03, 0.04, 0.05, 0.06, 0.07, 0.08, 0.09 or 0.1.

According to an embodiment of the present disclosure, y is in a range of 0.1≤y≤2.5, preferably 0.5≤y≤1.5, and is exemplarily 0.01, 0.05, 0.1, 0.5, 1, 1.5, 2.5 or 2.9.

According to an embodiment of the present disclosure, based on the total mass of the green fluorescent ceramic material, a mass fraction of the graphene is less than or equal to 0.1 wt % and is not 0; preferably, a mass fraction of the graphene is less than or equal to 0.05 wt % and is not 0, and is exemplarily 0.001 wt %, 0.002 wt %, 0.004 wt %, 0.005 wt %, 0.006 wt %, 0.008 wt %, 0.01 wt %, 0.015 wt %, 0.02 wt %, 0.025 wt %, 0.03 wt %, 0.035 wt %, 0.04 wt %, 0.045 wt %, 0.05 wt %, 0.1 wt %, 0.2 wt %, 0.3 wt %, 0.4 wt % or 0.45 wt %.

According to an exemplary embodiment of the present disclosure, the green fluorescent ceramic material has a chemical composition of:
0.03 wt % graphene-Y_{2.989}Al₅O₁₂:0.001 Ce³⁺, 0.01 Lu³⁺;
0.05 wt % graphene-Y_{2.497}Al₅O₁₂:0.003 Ce³⁺, 0.5 Lu³⁺;
0.01 wt % graphene-Y_{1.493}Al₅O₁₂:0.007 Ce³⁺, 1.5 Lu³⁺; or
0.05 wt % graphene-Y_{0.0985}Al₅O₁₂:0.0015 Ce³⁺, 2.9 Lu³⁺.

According to an embodiment of the present disclosure, the green fluorescent ceramic material is a transparent ceramic material. For example, the green fluorescent ceramic material has a visible light transmittance of greater than or equal to 75%, preferably greater than or equal to 78%, and is exemplarily 75%, 76%, 78%, 79%, 80%, 81% or 82%.

According to an embodiment of the present disclosure, the green fluorescent ceramic material has a thermal conductivity of greater than 5 Wm⁻¹ K⁻¹, preferably greater than or equal to 7 Wm⁻¹ K⁻¹, more preferably greater than or equal to 10 Wm⁻¹ K⁻¹, and is exemplarily 7.0 Wm⁻¹ K⁻¹, 7.2 Wm⁻¹ K⁻¹, 10.0 Wm⁻¹ K⁻¹, 11.2 Wm⁻¹ K⁻¹, 12.1 Wm⁻¹ K⁻¹ or 13.2 Wm⁻¹ K⁻¹.

The present disclosure further provides a method for preparing the green fluorescent ceramic material described above, which comprises the following steps:
1) weighing out starting materials and mixing by ball-milling: weighing out graphene, Y₂O₃, Al₂O₃, Lu₂O₃ and a Ce-containing compound as starting materials according to the above chemical composition of the green fluorescent ceramic material, adding a sintering aid into the starting materials, and performing ball-milling to obtain a uniformly dispersed slurry;
2) preparing a ceramic green body; and
3) embedding the ceramic green body obtained in step 2) with a powder, and performing vacuum sintering to obtain the green fluorescent ceramic material.

According to an embodiment of the present disclosure, the sintering aid is one, two or more of CaO, MgO, SiO₂ and TEOS, preferably a combination of CaO and TEOS, MgO, or a combination of MgO and TEOS.

According to an embodiment of the present disclosure, the Ce-containing compound may be selected from CeO₂ and/or CeN₃O₉·6H₂O.

According to an embodiment of the present disclosure, based on the total weight of the green fluorescent ceramic material, when the sintering aid comprises CaO and/or MgO, a mass fraction of CaO or MgO is 0.001-0.01 wt %, for example 0.003-0.008 wt %, and is exemplarily 0.001 wt %, 0.002 wt %, 0.003 wt %, 0.004 wt %, 0.006 wt %, 0.008 wt % or 0.01 wt %.

According to an embodiment of the present disclosure, based on the total weight of the green fluorescent ceramic material, when the sintering aid comprises SiO₂ and/or TEOS, a mass fraction of SiO₂ or TEOS is 0.01-0.1 wt %, for example 0.03-0.08 wt %, and is exemplarily 0.01 wt %, 0.02 wt %, 0.03 wt %, 0.04 wt %, 0.06 wt %, 0.08 wt % or 0.1 wt %.

According to an embodiment of the present disclosure, the ball-milling is wet ball-milling. For example, a medium for the ball-milling is absolute ethanol or acetone. For example, the ball-milling is performed for a time period of 4-30 h, preferably 8-24 h.

According to an embodiment of the present disclosure, the preparation of the ceramic green body in step 2) specifically comprises: subjecting the slurry obtained in step 1) to drying, sieving, dry pressing and cold isostatic pressing molding, and dewaxing to obtain the ceramic green body.

According to an embodiment of the present disclosure, the drying is vacuum drying, for example, at a temperature of 50-70° C., preferably 55-65° C., and exemplarily 60° C.

According to an embodiment of the present disclosure, the sieving, dry pressing and cold isostatic pressing can be performed under operating conditions known in the art.

According to an embodiment of the present disclosure, the sieving is performed through a 150 to 200-mesh sieve.

According to an embodiment of the present disclosure, the dewaxing is performed at a temperature of 250-600° C., preferably 400-550° C., and exemplarily 450° C., 500° C. or 550° C. For example, the dewaxing is performed for a time period of 2-10 h, preferably 4-8 h, and exemplarily 2 h, 4 h, 6 h, 8 h or 10 h.

According to an embodiment of the present disclosure, the powder for the embedding does not react with the ceramic green body. For example, the powder for the embedding is one of or a mixture of two of Al₂O₃ and Y₂O₃.

According to an embodiment of the present disclosure, in step 3), the powder needs to be subjected to calcination and crushing treatment at least once before the embedding.

According to an embodiment of the present disclosure, before the embedding, the powder for the embedding is subjected to calcination and crushing (by grinding) in air at least once, for example, at least twice. The calcination is performed at a temperature of 1500-1750° C., preferably 1650-1750° C., and exemplarily 1500° C., 1600° C., 1650° C., 1700° C. or 1750° C. The calcination is performed for a time period of 4-15 h, preferably 6-10 h, and exemplarily 4 h, 5 h, 6 h, 8 h, 10 h, 12 h or 15 h.

According to an embodiment of the present disclosure, the powder for the embedding that has been subjected to calcination and crushing treatment at least once needs to be further sieved, for example, through a 60 to 150-mesh sieve.

According to an embodiment of the present disclosure, the embedding is performed by uniformly covering a surface, preferably an upper surface and a lower surface, of the ceramic green body with the powder for the embedding. Preferably, a thickness for the embedding is 0.3-0.6 mm, for example 0.4-0.5 mm.

According to an embodiment of the present disclosure, before the vacuum sintering, the ceramic green body is embedded with the treated Al₂O₃ and/or Y₂O₃ embedding powder, wherein the embedding powder is sieved through a 60 to 150-mesh sieve and then uniformly covers an upper surface and a lower surface of the ceramic green body; preferably, a thickness of the embedding powder covering each of the upper surface and the lower surface of the ceramic green body is 0.3-0.6 mm.

According to an embodiment of the present disclosure, the vacuum sintering is performed at a temperature of 1600-1750° C., preferably 1650-1750° C., and more preferably 1650-1700° C.

According to an embodiment of the present disclosure, the vacuum sintering is performed with a holding time of 2-20 h, preferably 4-15 h, and more preferably 6-10 h.

According to an exemplary embodiment of the present disclosure, the method for preparing the green fluorescent ceramic material comprises the following steps:
a) taking graphene, Y₂O₃, Al₂O₃, Lu₂O₃, as well as CeO₂ and/or CeN₃O₉·6H₂O as starting materials, and accurately weighing out each of the starting materials according to the above chemical composition of the green fluorescent ceramic material;
b) adding a sintering aid to the above-formulated starting materials to obtain a mixed material;
c) taking absolute ethanol or acetone as a medium, and performing wet ball-milling on the mixed material to obtain a uniformly dispersed slurry;
d) subjecting the slurry to vacuum drying, sieving, dry pressing and cold isostatic pressing molding and a dewaxing procedure to obtain a ceramic green body; and
e) taking Al₂O₃ and/or Y₂O₃ that have been subjected to calcination and crushing treatment at least once as an embedding powder, embedding an upper surface and a lower surface of the ceramic green body, and then performing vacuum sintering to obtain the green fluorescent ceramic material.

The present disclosure further provides use of the green fluorescent ceramic material described above in LEDs, preferably as an LED encapsulating material. For example, the green fluorescent ceramic material is ground and polished to a size required by LED encapsulating, such as 0.1-2.0 mm, to obtain a green fluorescent transparent ceramic suitable for LED encapsulating.

The present disclosure further provides an LED encapsulating material, which comprises the green fluorescent ceramic material.

The present disclosure further provides an LED device, preferably an LED lighting device, which comprises the green fluorescent ceramic material.

Preferably, the green fluorescent ceramic material is an encapsulating material for an LED device.

Preferably, the LED device has a luminous efficiency of no less than 160 lm/W, for example, no less than 165 lm/W.

Preferably, the LED device has a luminescence peak wavelength in the green light region (490-540 nm).

Preferably, the LED lighting device is a green LED lighting device; more preferably, the LED lighting device is a green LED fish gathering lamp.

### Beneficial Effects of Present Disclosure:

The present disclosure overcomes the existing methods' disadvantage of having strict requirements for equipment, reduces the production cost of graphene-fluorescent ceramic composite material, and provides a green fluorescent ceramic material with high luminous efficiency and good heat dissipation performance. In addition, the material is a transparent ceramic material.

The introduction of a small amount of graphene by means of vacuum sintering greatly improves the heat dissipation performance of the green fluorescent ceramic material, making the material suitable for serving as an encapsulating material for high-power LED high-end lighting.

Through the powder embedding, the formation of oxygen vacancies in vacuum sintering is inhibited, the annealing procedure in air and the decomposition of graphene in the procedure are avoided, and a green fluorescent ceramic material with good heat dissipation performance is prepared.

The use of the green fluorescent ceramic material with good heat dissipation performance as an encapsulating material is beneficial to the thermal management of high-power LED lighting and to improvements in its lifetime.

### BRIEF DESCRIPTION OF THE DRAWINGS

FIG. 1 is a graph showing a curve of the transmittance of the green fluorescent transparent ceramic in Example 1.

FIG. 2 is an emission spectrum of the green fluorescent transparent ceramic in Example 1.

FIG. 3 is a pictorial diagram of the green fluorescent transparent ceramic product in Example 2.

FIG. 4 is an emission spectrum of the YAG:Ce fluorescent ceramic in Comparative Example 2.

FIG. 5 is a pictorial diagram of the ceramic product without powder-embedding and sintering treatments in Comparative Example 4.

### DETAILED DESCRIPTION

The technical scheme of the present disclosure will be further illustrated in detail with reference to the following specific examples. It should be understood that the following embodiments are merely exemplary illustration and explanation of the present disclosure, and should not be construed as limiting the protection scope of the present disclosure. All techniques implemented based on the content of the present disclosure described above are encompassed within the protection scope of the present disclosure.

Unless otherwise stated, the starting materials and reagents used in the following examples are all commercially available products or can be prepared using known methods.

### Example 1

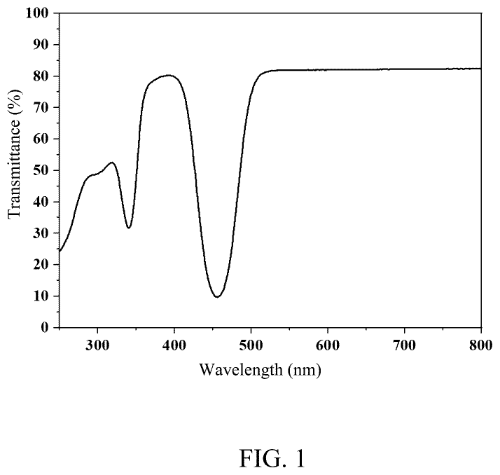

According to the chemical composition of 0.03 wt % graphene-Y_{2.989}Al₅O₁₂:0.001 Ce³⁺, 0.01 Lu³⁺, 0.003 g of graphene, 5.6451 g of Y₂O₃, 4.2639 g of α-Al₂O₃, 0.0332 g of Lu₂O₃ and 0.0029 g of CeO₂ were sequentially weighed out as starting materials, and 0.004 g of CaO and 0.05 g of TEOS were added as sintering aids. The above starting materials and absolute ethanol were loaded into a ball-milling jar, and ball-milled with alumina milling balls for 24 h at a rotation speed of 250 r/min. After the slurry obtained from ball-milling was fully dried in a vacuum oven at 60° C., the resulting powder was subjected to sieving and dry pressing molding, and then pressed into a green body by cold isostatic pressing at 200 MPa. Another Y₂O₃ powder was subjected to calcination (at 1750° C. for 8 h) and crushing by grinding in air twice, and was used as an embedding powder. After the green body was subjected to dewaxing for 10 h at 500° C. in a muffle furnace, 0.5 mm of the Y₂O₃ embedding powder was spread on an upper surface and a lower surface of the green body, and then the green body was sintered in a vacuum tungsten coil furnace at 1730° C. for 4 h. The ceramic product was ground and polished to 0.8 mm to obtain a green fluorescent transparent ceramic with a visible light transmittance of 82% (as shown in FIG. 1) and a thermal conductivity of 13.2 Wm⁻¹ K⁻¹.

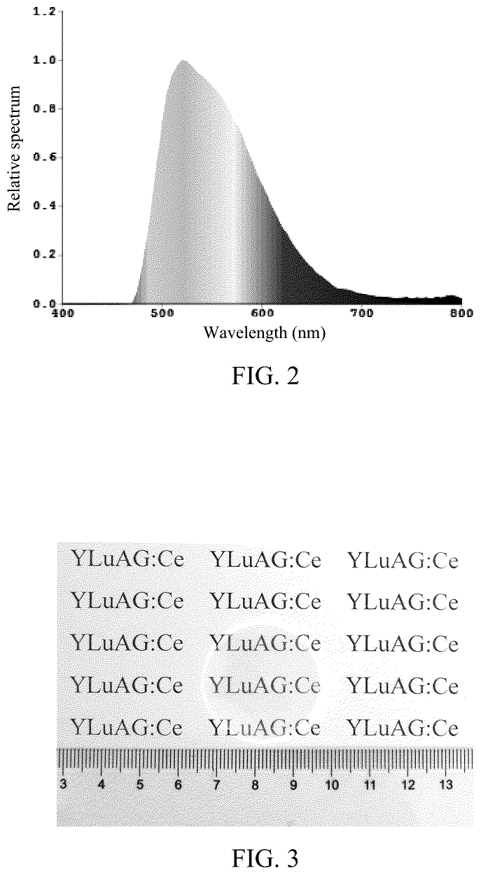

The prepared green fluorescent transparent ceramic was encapsulated together with a 150 W blue LED chip to give an LED device. At room temperature, the LED device was driven by a constant current of 2650 mA, and the performance indexes determined by the tests were as follows:
luminous efficiency: 162 lm/W, peak wavelength: 532 nm (as shown in FIG. 2).

It can be seen that the light color quality and thermal conductivity of the green transparent ceramic phosphor in this example were excellent enough to meet the needs of LED special lighting.

### Example 2

According to the chemical composition of 0.05 wt % graphene-Y_{1.495}Al₅O₁₂:0.003 Ce³⁺, 0.5 Lu³⁺, 0.003 g of graphene, 4.4227 g of Y₂O₃, 3.9989 g of α-Al₂O₃, 1.5573 g of Lu₂O₃, 0.0204 g of CeN₃O₉·6H₂O and 0.005 g of MgO were weighed out as starting materials to prepare a green fluorescent transparent ceramic. The differences from Example 1 were as follows: the green body was subjected to dewaxing at 450° C. for 8 h, and the vacuum sintering was performed at 1700° C. for 6 h. The other conditions were the same as in Example 1, and a green fluorescent transparent ceramic material (as shown in FIG. 3) was obtained. The ceramic material was ground and polished to 1.0 mm to obtain a green fluorescent transparent ceramic with a visible light transmittance of 80% and a thermal conductivity of 12.1 Wm⁻¹ K⁻¹.

The prepared green fluorescent transparent ceramic was encapsulated to give an LED device, and the performance of the device was tested. The encapsulating and testing conditions were the same as in Example 1. The performance indexes determined by the tests were as follows:
luminous efficiency: 170 lm/W, peak wavelength: 528 nm.

FIG. 3 is a pictorial diagram of the green fluorescent transparent ceramic product in Example 2. It can be seen from FIG. 3 and the above test results that the transparency, light color quality and thermal conductivity of the green transparent ceramic phosphor in this example were excellent enough to meet the needs of LED special lighting.

### Example 3

According to the chemical composition of 0.01 wt % graphene-Y_{1.493}Al₅O₁₂:0.007 Ce³⁺, 1.5 Lu³⁺, 0.001 g of graphene, 2.3230 g of Y₂O₃, 3.5128 g of α-Al₂O₃, 4.1041 g of Lu₂O₃, 0.0166 g of CeO₂, 0.0045 g of MgO and 0.03 g of TEOS were weighed out as starting materials to prepare a green fluorescent transparent ceramic. The differences from Example 1 were as follows: the Al₂O₃ embedding powder was calcined at 1700° C. for 10 h and then crushed, and the thickness for the powder embedding of the green body was 0.4 mm; the green body was subjected to dewaxing at 400° C. for 8 h; the vacuum sintering was performed at 1680° C. for 10 h. The other conditions were the same as in Example 1, and a green fluorescent transparent ceramic material was obtained. The ceramic material was ground and polished to 1.2 mm to obtain a green fluorescent transparent ceramic with a visible light transmittance of 79% and a thermal conductivity of 11.2 Wm⁻¹ K⁻¹.

The prepared green fluorescent transparent ceramic was encapsulated to give an LED device, and the performance of the device was tested. The encapsulating and testing conditions were the same as in Example 1. The performance indexes determined by the tests were as follows:
luminous efficiency: 160 lm/W, peak wavelength: 523 nm.

It can be seen that the light color quality and thermal conductivity of the green transparent ceramic phosphor in this example were excellent enough to meet the needs of LED special lighting.

### Example 4

According to the chemical composition of 0.05 wt % graphene-Y_{0.0985}Al₅O₁₂:0.0015 Ce³⁺, 2.9 Lu³⁺, 0.005 g of graphene, 0.1311 g of Y₂O₃, 3.0047 g of α-Al₂O₃, 6.7870 g of Lu₂O₃, 0.0030 g of CeO₂, 0.005 g of CaO and 0.05 g of TEOS were weighed out as starting materials to prepare a green fluorescent transparent ceramic. The differences from Example 1 were as follows: the Y₂O₃ embedding powder was calcined at 1700° C. for 10 h and then crushed, and the thickness for the powder embedding of the green body was 0.3 mm; the green body was subjected to degreasing at 500° C. for 8 h; the vacuum sintering was performed at 1700° C. for 8 h. The other conditions were the same as in Example 1, and a green fluorescent transparent ceramic material was obtained. The ceramic material was ground and polished to 0.6 mm to obtain a green fluorescent transparent ceramic with a visible light transmittance of 82% and a thermal conductivity of 7.2 Wm⁻¹ K⁻¹.

The prepared green fluorescent transparent ceramic was encapsulated to give an LED device, and the performance of the device was tested. The encapsulating and testing conditions were the same as in Example 1. The performance indexes determined by the tests were as follows:
luminous efficiency: 175 lm/W, peak wavelength: 511 nm.

It can be seen that the light color quality and thermal conductivity of the green transparent ceramic phosphor in this example were excellent enough to meet the needs of LED special lighting.

### Comparative Example 1

According to the chemical composition of Y_{0.0985}Al₅O₁₂:0.0015 Ce³⁺, 2.9 Lu³⁺, 0.1312 g of Y₂O₃, 3.0062 g of α-Al₂O₃, 6.7904 g of Lu₂O₃, 0.0030 g of CeO₂, 0.005 g of CaO and 0.05 g of TEOS were weighed out as starting materials to prepare a green fluorescent transparent ceramic. Other preparation, encapsulating and testing conditions were the same as in Example 4. The prepared ceramic had a visible light transmittance of 82% and a thermal conductivity of 5.9 Wm⁻¹ K⁻¹.

The performance indexes of the LED device obtained from encapsulation were as follows:
luminous efficiency: 172 lm/W, peak wavelength: 510 nm.

It can be seen that in this comparative example, the ceramic was not doped with graphene for modification, and the thermal conductivity was reduced. This reflects the superiority of doping YAG-based fluorescent ceramics with graphene in the present disclosure in modifying its thermal performance.

### Comparative Example 2

According to the chemical composition of Y_{2.9985}Al₅O₁₂:0.0015 Ce³⁺, 5.6710 g of Y₂O₃, 4.2699 g of α-Al₂O₃, 0.0043 g of CeO₂, 0.005 g of CaO and 0.05 g of TEOS were weighed out as starting materials to prepare a fluorescent transparent ceramic. Other preparation, encapsulating and testing conditions were the same as in Example 4. The prepared ceramic had a visible light transmittance of 82% and a thermal conductivity of 10.5 Wm⁻¹ K⁻¹.

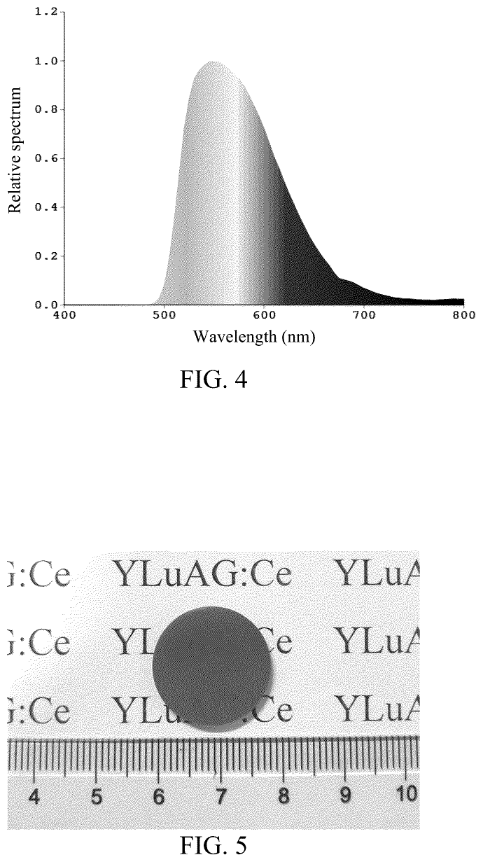

The performance indexes of the LED device obtained from encapsulation were as follows:
luminous efficiency: 158 lm/W, peak wavelength: 545 nm (as shown in FIG. 4).

It can be seen that in this comparative example, the ceramic was not doped with Lu³⁺, its luminescence wavelength was in the yellow light region, and the luminous efficiency was reduced compared to those in Example 4 and Comparative Example 1. This can further reflect the superiority of doping YAG:Ce fluorescent ceramics with Lu³⁺ in the present disclosure in modulating the luminescence wavelength and enhancing the luminous efficiency.

### Comparative Example 3

The green fluorescent ceramic with the chemical composition of 0.03 wt % graphene-Y_{2.989}Al₅O₁₂:0.001 Ce³⁺, 0.01 Lu³⁺ in Example 1 was prepared. The preparation conditions were the same as in Example 1, except that the sintering was performed under N₂ and normal pressure. The sintered product had low density and low transparency.

It can be seen that in this comparative example, the green body was sintered under normal pressure, and the sintering of the ceramic product was hindered by graphene, resulting in a decrease in density. This can further reflect the superiority of the vacuum-sintered graphene-modified green fluorescent transparent ceramic proposed in the present disclosure.

### Comparative Example 4

According to the procedures in Example 2, a fluorescent ceramic with a chemical composition of 0.05 wt % graphene-Y_{1.495}Al₅O₁₂:0.003 Ce³⁺, 0.5 Lu³⁺ was prepared. The preparation conditions were the same as in Example 2, except that the ceramic was not subjected to powder embedding before vacuum sintering. The obtained ceramic product had a high density and poor transparency, and a large number of oxygen vacancy defects were formed due to vacuum sintering, the obtained ceramic product was dark brown (as shown in FIG. 5). The obtained ceramic product had a luminous intensity much lower than that of the green fluorescent ceramic product prepared in Example 2.

It can be seen that all the LED devices with encapsulated green fluorescent ceramics in the present disclosure had a peak wavelength in the green light region, high luminous efficiency and excellent heat dissipation performance, which can meet the needs of high-power LED high-end lighting and also reflect the excellent performance of the green fluorescent transparent ceramics in the present disclosure.

The embodiments of the present disclosure have been described above. However, the present disclosure is not limited to the embodiments described above. Any modification, equivalent substitution, improvement and the like made without departing from the spirit and principle of the present disclosure shall fall within the protection scope of the present disclosure.

1. A green fluorescent ceramic material, wherein the green fluorescent ceramic material has a chemical composition of graphene-Y_{3-x-y}Al₅O₁₂:x Ce³⁺, y LU³⁺ with 0.0001≤x≤0.1, and 0.01≤y≤2.9; and based on the total weight of the green fluorescent ceramic material, a mass percentage of the graphene is less than 0.5 wt % but is not 0.

2. The material as claimed in claim 1, wherein x is in a range of 0.0005≤x≤0.06, preferably 0.001≤x≤0.01;
preferably, y is in a range of 0.1≤y≤2.5, preferably 0.5≤y≤1.5;
preferably, based on the total mass of the green fluorescent ceramic material, the mass fraction of the graphene is less than or equal to 0.1 wt % and is not 0; preferably, the mass fraction of the graphene is less than or equal to 0.05 wt % and is not 0.

3. The material as claimed in claim 1, wherein the green fluorescent ceramic material has a chemical composition of:
0.03 wt % graphene-Y_{2.989}Al₅O₁₂:0.001 Ce³⁺, 0.01 Lu³⁺;
0.05 wt % graphene-Y_{2.497}Al₅O₁₂:0.003 Ce³⁺, 0.5 Lu³⁺;
0.01 wt % graphene-Y_{1.493}Al₅O₁₂:0.007 Ce³⁺, 1.5 Lu³⁺; or
0.05 wt % graphene-Y_{0.0985}Al₅O₁₂:0.0015 Ce³⁺, 2.9 Lu³⁺.

4. The material as claimed in claim 1, wherein the green fluorescent ceramic material is a transparent ceramic material;
for example, the green fluorescent ceramic material has a visible light transmittance of greater than or equal to 75%, preferably greater than or equal to 78%;
preferably, the green fluorescent ceramic material has a thermal conductivity of greater than 5 Wm⁻¹ K⁻¹, preferably greater than or equal to 7 Wm⁻¹ K⁻¹, and more preferably greater than or equal to 10 Wm⁻¹ K⁻¹.

5. A method for preparing the green fluorescent ceramic material as claimed in claim 1, comprising the following steps:
1) weighing out starting materials and mixing by ball-milling: weighing out graphene, Y₂O₃, Al₂O₃, Lu₂O₃ and a Ce-containing compound as starting materials according to the above chemical composition of the green fluorescent ceramic material, adding a sintering aid into the starting materials, and performing ball-milling to obtain a uniformly dispersed slurry;
2) preparing a ceramic green body; and
3) embedding the ceramic green body obtained in step 2) with a powder, and performing vacuum sintering to obtain the green fluorescent ceramic material.

6. The method as claimed in claim 5, wherein the sintering aid is one, two or more of CaO, MgO, SiO₂ and TEOS, preferably a combination of CaO and TEOS, MgO, or a combination of MgO and TEOS;
preferably, the Ce-containing compound is selected from CeO₂ and/or CeN₃O₉·6H₂O;
preferably, based on the total weight of the green fluorescent ceramic material, when the sintering aid comprises CaO and/or MgO, a mass fraction of CaO or MgO is 0.001-0.01 wt %, for example 0.003-0.008 wt %;
preferably, based on the total weight of the green fluorescent ceramic material, when the sintering aid comprises SiO₂ and/or TEOS, a mass fraction of SiO₂ or TEOS is 0.01-0.1 wt %, for example 0.03-0.08 wt %;
preferably, the ball-milling is wet ball-milling; for example, a medium for the ball-milling is absolute ethanol or acetone; for example, the ball-milling is performed for a time period of 4-30 h;
preferably, the preparation of the ceramic green body in step 2) specifically comprises: subjecting the slurry obtained in step 1) to drying, sieving, dry pressing and cold isostatic pressing molding, and dewaxing to obtain the ceramic green body;
preferably, the sieving is performed through a 150 to 200-mesh sieve;
preferably, the degreasing is performed at a temperature of 250-600° C., preferably 400-550° C.; for example, the degreasing is performed for a time period of 2-10 h, preferably 4-8 h.

7. The method as claimed in claim 5, wherein the powder for the embedding is one of or a mixture of two of Al₂O₃ and Y₂O₃;
preferably, in step 3), the powder needs to be subjected to calcination and crushing treatment at least once before the embedding;
preferably, before the embedding, the powder for the embedding is subjected to calcination and crushing in air at least once, for example, at least twice; preferably, the calcination is performed at a temperature of 1500-1750° C., preferably 1650-1750° C.; preferably, the calcination is performed for a time period of 4-15 h, preferably 6-10 h;
preferably, the powder for the embedding that has been subjected to calcination and crushing treatment at least once needs to be further sieved;
preferably, the embedding is performed by uniformly covering a surface, preferably an upper surface and a lower surface, of the ceramic green body with the powder for the embedding; preferably, a thickness for the embedding is 0.3-0.6 mm, for example 0.4-0.5 mm;
preferably, the vacuum sintering is performed at a temperature of 1600-1750° C., preferably 1650-1750° C.;
preferably, the vacuum sintering is performed with a holding time of 2-20 h, preferably 4-15 h.

8. The method as claimed in claim 5, wherein the method for preparing the green fluorescent ceramic material comprises the following steps:
a) taking graphene, Y₂O₃, Al₂O₃, Lu₂O₃, as well as CeO₂ and/or CeN₃O₉·6H₂O as starting materials, and weighing out each of the starting materials according to the above chemical composition of the green fluorescent ceramic material;
b) adding a sintering aid to the above-formulated starting materials to obtain a mixed material;
c) taking absolute ethanol or acetone as a medium, and performing wet ball-milling on the mixed material to obtain a uniformly dispersed slurry;
d) subjecting the slurry to vacuum drying, sieving, dry pressing and cold isostatic pressing molding and a dewaxing procedure to obtain a ceramic green body; and
e) taking Al₂O₃ and/or Y₂O₃ that have been subjected to calcination and crushing treatment at least once as an embedding powder, embedding an upper surface and a lower surface of the ceramic green body, and then performing vacuum sintering to obtain the green fluorescent ceramic material.

9. Use of the green fluorescent ceramic material as claimed in claim 1 in LEDs, preferably as an LED encapsulating material.

10. An LED encapsulating material or an LED device comprising the green fluorescent ceramic material as claimed in claim 1;
preferably, the LED device has a luminous efficiency of no less than 160 lm/W, for example, no less than 165 lm/W;
preferably, the LED device has a luminescence peak wavelength in the green light region (490-540 nm);
preferably, the LED device is an LED lighting device;
preferably, the LED lighting device is a green LED lighting device; more preferably, the LED lighting device is a green LED fish gathering lamp.
